(19) United States
(12) Patent Application Publication
(10) Pub. No.: US 2014/0284757 A1
(43) Pub. Date: Sep. 25, 2014

(54) SEMICONDUCTOR DEVICE

(71) Applicant: KABUSHIKI KAISHA TOSHIBA, Minato-ku (JP)

(72) Inventor: Hideaki Sai, Hyogo-ken (JP)

(73) Assignee: KABUSHIKI KAISHA TOSHIBA, Minato-ku (JP)

(21) Appl. No.: 14/023,307

(22) Filed: Sep. 10, 2013

(30) Foreign Application Priority Data
Mar. 25, 2013 (JP) 2013-034711

(51) Int. Cl. H01L 29/06; H01L 29/861

(52) U.S. Cl. CPC H01L 29/0626; H01L 29/8611; H01L 29/0619
USPC 257/494

(57) ABSTRACT

A semiconductor device includes a semiconductor substrate, a first semiconductor layer, a second semiconductor layer, a third semiconductor layer, a first electrode, and a second electrode. The semiconductor substrate is of a first conductivity type. The first semiconductor layer is of a second conductivity type, provided on the semiconductor substrate. The second semiconductor layer is of a first conductivity type, reaches the semiconductor substrate from a surface of the first semiconductor layer, and surrounds the first semiconductor layer. The third semiconductor layer is of a second conductivity type, separated from the second semiconductor layer, surrounded by the second semiconductor layer, and has a higher concentration of second-conductivity-type impurities than the first semiconductor layer. In addition, a withstand voltage between the semiconductor substrate and the third semiconductor layer is lower than the withstand voltage between the second semiconductor layer and the third semiconductor layer.

### CROSS REFERENCE TO RELATED APPLICATION

This application is based upon and claims the benefit of priority from the prior Japanese Patent Application No. 2013-034711, filed on Feb. 25, 2013, the entire contents of which are incorporated herein by reference.

### FIELD

Embodiments described herein generally relate to a semiconductor device.

### BACKGROUND

An ESD protection diode is connected between an input terminal and an output terminal of a semiconductor device to protect the semiconductor device from breakdown due to ESD (Electro Static Discharge).

Produced semiconductor devices each include an ESD protection diode only as a semiconductor element inside a chip, or an ESD protection diode and a semiconductor element to be protected inside a chip. As an area of a p-n junction diode increases, ESD tolerance of the ESD protection diode becomes higher.

Unfortunately, as the area of the p-n junction diode is increased to enhance the ESD tolerance, a chip area becomes larger to thereby increase production costs of chips.

### BRIEF DESCRIPTION OF THE DRAWINGS

The accompanying drawings, which are incorporated in and constitute a part of this specification, illustrate embodiments of the invention and together with the description, serve to explain the principles of the invention.

FIG. 1 is a sectional view showing a semiconductor device according to a first embodiment.

FIG. 2 is a plan view showing the semiconductor device according to the embodiment.

FIG. 3 is a plan view showing a semiconductor device according to a first modification of the first embodiment.

FIG. 4 is a sectional view showing a semiconductor device according to a comparative example.

FIG. 5 is a sectional view showing a semiconductor device according to a second modification of the first embodiment.

FIG. 6 is a sectional view showing the semiconductor device according to a second embodiment.

FIG. 7 is a sectional view showing the semiconductor device according to a third embodiment.

FIG. 8 is a sectional view showing the semiconductor device according to a fourth embodiment.

### DETAILED DESCRIPTION

According to an embodiment, a semiconductor device includes a semiconductor substrate, a first semiconductor layer, a second semiconductor layer, a third semiconductor layer, a first electrode, and a second electrode. The semiconductor substrate is of a first conductivity type. The first semiconductor layer is of a second conductivity type, provided on the semiconductor substrate. The second semiconductor layer is of a first conductivity type, reaches the semiconductor substrate from a surface of the first semiconductor layer, and surrounds the first semiconductor layer. The third semiconductor layer is of a second conductivity type, separated from the second semiconductor layer, surrounded by the second semiconductor layer, and has a higher concentration of second-conductivity-type impurities than the first semiconductor layer. The first electrode is connected to the semiconductor substrate. The second electrode is connected to the second semiconductor layer. In addition, a withstand voltage between the semiconductor substrate and the third semiconductor layer is lower than the withstand voltage between the second semiconductor layer and the third semiconductor layer.

Embodiments will be described with reference to drawings. The drawings are conceptual. A relationship between a shape and dimension of each portion and a proportionality factor among respective portions may not be necessarily the same as an actual one. Even when the same portions are drawn, their sizes or proportionality factors may be different from each other with respect to the drawings, and may be modified within the scope of the invention. Throughout the specification, a first conductivity type and a second conductivity type will be described as an n-type and a p-type, respectively, and vice versa. Although silicon exemplifies a semiconductor in the detailed description, silicon carbide (SiC) or nitride semiconductors including AlGaN may be employed. When n-type conductivity is denoted by n⁺, n, and n⁻, n-type impurity concentrations are assumed to become lower in this order. When p-type conductivity is denoted by p and p⁻, p-type impurity concentrations are assumed to become lower in this order. A semiconductor device in accordance with each embodiment includes an ESD protection diode only, or includes an ESD protection diode and another semiconductor element. The ESD protection diode only will be simply described as a substantial portion of each embodiment.

### First Embodiment

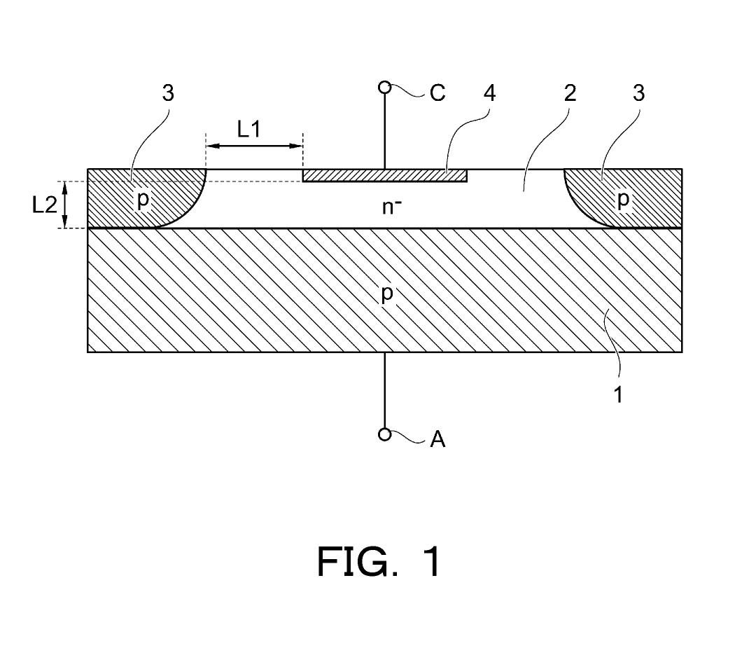

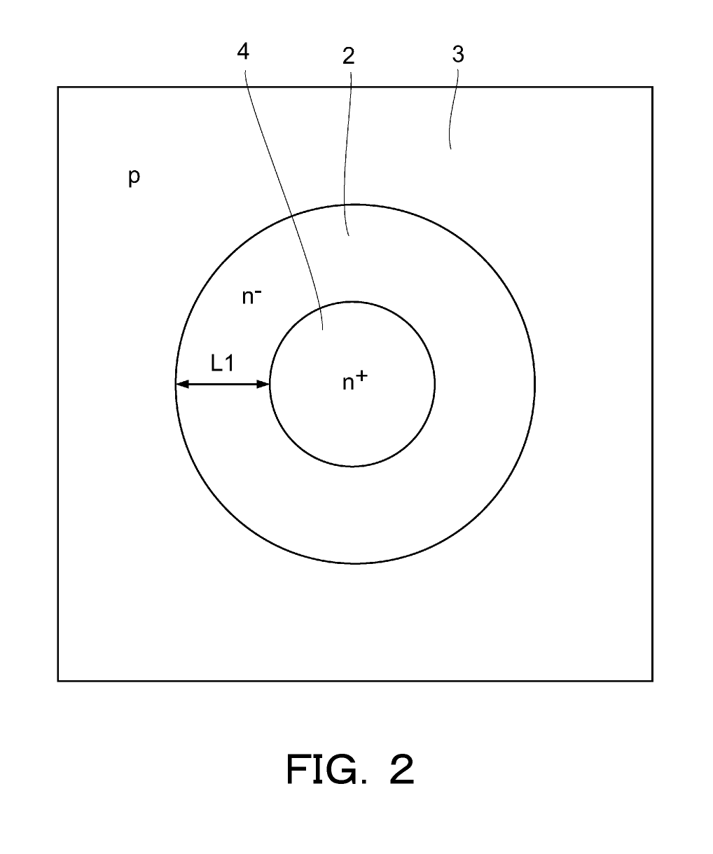

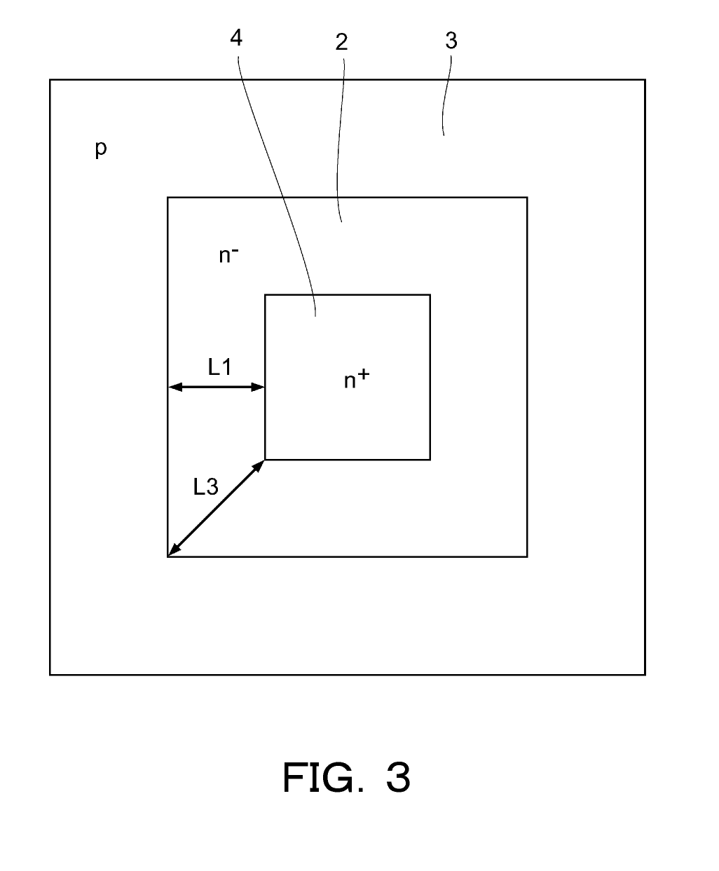

A semiconductor device in accordance with a first embodiment will be described with reference to FIGS. 1 to 3. FIG. 1 is a sectional view showing the semiconductor device in accordance with the first embodiment. FIG. 2 is a plan view showing the semiconductor device in accordance with the embodiment. FIG. 3 is a plan view showing a semiconductor device in accordance with a first modification of the embodiment.

As shown in FIGS. 1 and 2, the semiconductor device in accordance with the embodiment includes a p-type semiconductor substrate 1 (semiconductor substrate of first conductivity type), an n⁻-type epitaxial layer 2 (first semiconductor layer of second conductivity type), a p⁻type semiconductor layer 3 (second semiconductor layer of first conductivity type), an n⁺-type contact layer 4 (third semiconductor layer of second conductivity type), an anode electrode A (first electrode) and a cathode electrode C (second electrode). For example, silicon is included in the p-type semiconductor substrate 1, the n⁻-type epitaxial layer 2, and the n⁺-type contact layer 4.

The n⁻-type epitaxial layer 2 is an n-type semiconductor, and is epitaxially grown on the p-type semiconductor substrate 1. The n⁻-type epitaxial layer 2 has an n-type impurity concentration of 1×10¹³/cm³ to 1×10¹⁴/cm³, for example.

The p-type semiconductor layer 3 reaches the p-type semiconductor substrate 1, and surrounds the n⁻-type epitaxial layer 2. As shown in FIG. 2, the n⁻-type epitaxial layer 2 is surrounded by the p-type semiconductor layer 3, and is circular in shape, for example.

The n⁺-type contact layer 4 is selectively provided to the n⁻-type epitaxial layer 2. The n⁺-type contact layer 4 is separated by the n⁻-type epitaxial layer 2 from the p-type semiconductor layer 3. As shown in FIG. 2, the n⁺-type contact layer 4 is located substantially at the center of the n⁻-type epitaxial layer 2, and is circular in shape, for example. The n⁺-type contact layer 4 has n-type impurity concentrations of, e.g., 1×10¹⁹/cm³ to 1×10²⁰/cm³, which is higher than the n-type impurity concentration of the n⁻-type epitaxial layer 2. Although the center of the circular n⁺-type contact layer 4 is desired to be the same as the center of the circular n⁻-type epitaxial layer 2 in the plan view, both the centers are not limited to this.

The p-type semiconductor layer 3 and the n⁺-type contact layer 4 are impurity diffused layers. The impurity diffused layers are made by injecting impurities to portions of the n⁻-type epitaxial layer 2, which is followed by heat treatment to cause the portions to be the p-type semiconductor layer 3 and the n⁺-type contact layer 4. The method of forming the p-type semiconductor layer 3 and the n⁺-type contact layer 4 is not limited to this. Alternatively, the p-type semiconductor layer 3 and the n⁺ type contact layer 4 may be formed such that the layers 3 and 4 are embedded in preliminarily removed portions of the n⁻-type epitaxial layer 2. Alternatively, the p-type semiconductor layer 3 may be a portion of the p-type semiconductor substrate 1.

A shortest separation distance between the n⁺-type contact layer 4 and the p-type semiconductor layer 3 is denoted as L1 on the surface of the n⁻-type epitaxial layer 2. When the center of the circular n⁺-type contact layer 4 coincides with the center of the circular n⁻-type epitaxial layer 2, the separation distance L1 between the n⁺-type contact layer 4 and the p-type semiconductor layer 3 is unchanged in any radial direction. In contrast, when the both centers do not coincide with each other, the separation distance L1 depends basically on a radial direction. In the embodiment, the centers of the two layers 3 and 4 are assumed to substantially coincide with each other.

L2 denotes a separation distance between the bottom of the n⁺-type contact layer 4 and the upper surface of the p-type semiconductor substrate 1. In the n⁺-type contact layer 4, the n-type impurity concentration decreases from the surface to bottom of the n⁺-type contact layer 4. The n-type impurity concentration of the n⁺-type contact layer 4 is the same as the n-type impurity concentration of the n⁻-type epitaxial layer 2 at the bottom of the n⁺-type contact layer 4. In the semiconductor device of the embodiment, the thickness of the n⁻-type epitaxial layer 2 and the shape of the n⁺-type contact layer 4 on the surface of the n⁻-type epitaxial layer 2 are set such that L1 is larger than L2, i.e., L1>L2.

The anode electrode A is electrically connected to the p-type semiconductor substrate 1. The anode electrode A is electrically connected to a back surface of the p-type semiconductor substrate 1. The back surface is on the opposite side of the p-type semiconductor substrate 1 from the n⁻-type epitaxial layer 2. Alternatively, the anode electrode A may be electrically connected to the p-type semiconductor substrate 1 through the p-type semiconductor layer 3 from the side of the n⁻ type epitaxial layer 2. The cathode electrode C is electrically connected to the n⁺ type contact layer 4.

A breakdown occurs at a portion of the semiconductor device of the embodiment when a reverse bias voltage is applied between the anode electrode A and the cathode electrode C and when the portion with a shortest distance has a lowest withstand voltage between the p-type semiconductor layer 3 and the n⁺-type contact layer 4 or between the p-type semiconductor substrate 1 and the n⁺-type contact layer 4. Since the semiconductor device of the embodiment has a relation of L2<L1, the withstand voltage between the n⁺-type contact layer 4 and the p-type semiconductor substrate 1 is the lowest to cause a breakdown in a direction vertical to the n⁻-type epitaxial layer 2 (the direction will be referred to as the vertical direction hereinafter). In the semiconductor device of the embodiment, the withstand voltage between the p-type semiconductor substrate 1 and the n⁺-type contact layer 4 is lower than the withstand voltage between the p-type semiconductor layer 3 and the n⁺-type contact layer 4. As a result, a breakdown current flows toward the p-type semiconductor substrate 1 from the bottom of the n⁺-type contact layer 4.

The semiconductor device of the embodiment just has to include a sectional structure shown in FIG. 1, and may have a planar structure shown in FIG. 3 in addition to FIG. 2. FIG. 3 is a plan view showing a semiconductor device in accordance with a first modification of the embodiment. As shown in FIG. 3, the n⁻-type epitaxial layer 2 and the n⁺-type contact layer 4 are quadrangular in planar shape. In the first modification, the centers of the two quadrangles coincide with each other. On the surface of the n⁻-type epitaxial layer 2, a relation of L3>L1 holds, provided that L1 denotes a shortest distance between a side of the quadrangular n⁺-type contact layer 4 and a side of the quadrangular p-type semiconductor layer 3, and L3 denotes a shortest distance between a corner of the quadrangular n⁺-type contact layer 4 and a corner of the inner quadrangle of the p-type semiconductor layer 3.

Also in the first modification, a relation of L2<L1 holds so that a withstand voltage between the p-type semiconductor substrate 1 and the n⁺-type contact layer 4 is lower than the withstand voltage between the p-type semiconductor layer 3 and the n⁺-type contact layer 4. As a result, a breakdown current flows toward the p-type semiconductor substrate 1 from the bottom of the n⁺-type contact layer 4. Whenever the ESD protection diode has a relation of L2<L1, which is a substantial portion of the semiconductor device of the embodiment, the ESD diode may have any structure shown by a plan view other than the plan views of FIGS. 2 and 3.

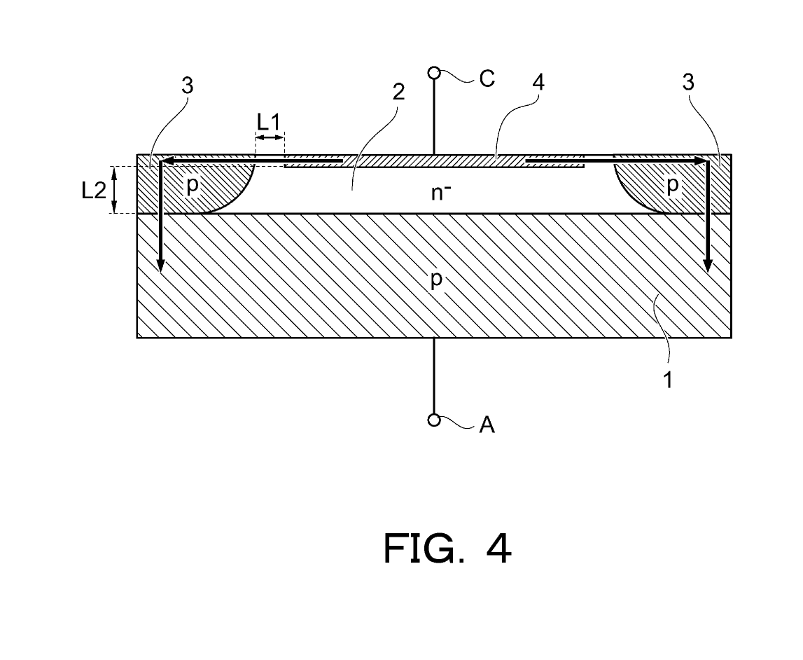

FIG. 4 is a sectional view showing a semiconductor device in accordance with a comparative example. As shown in FIG. 4, the semiconductor device has a relation of L2>L1 holds in accordance with the comparative example. L1 denotes a horizontal distance between the n⁺-type contact layer 4 and the p-type semiconductor layer 3 in a direction parallel to the n⁻ epitaxial layer 2 (referred to as the horizontal direction below). L2 denotes a vertical distance between the n⁺-type contact layer 4 and the p-type semiconductor substrate 1 in a direction vertical to the n⁻ epitaxial layer 2 (referred to as the vertical direction hereinafter). The semiconductor device of the comparative example differs from the semiconductor device of the embodiment in the relation between the distances L1 and L2.

A breakdown can occur between the n⁺-type contact layer 4 and the p-type semiconductor layer 3 in the semiconductor device in accordance with the comparative example. As shown by the arrows in FIG. 4, a breakdown current flows over the surface of the n⁻-type epitaxial layer 2 from the side of the n⁺-type contact layer 4. Subsequently, the breakdown current flows into the p-type semiconductor substrate 1 through the p-type semiconductor layer 3. The breakdown current concentrates on the sidewall of the n⁺-type contact layer 4 to thereby tend to break the ESD protection diode. ESD is caused by the breakdown of the ESD protection diode. As a result, the ESD protection diode has low ESD tolerance in the semiconductor device in accordance with the comparative example.

In contrast, a relation of L1>L2 holds in the semiconductor device in accordance with the embodiment. A breakdown can occur in the vertical direction between the n⁺-type contact layer 4 and the p-type semiconductor substrate 1 in the semiconductor device of the embodiment. A breakdown current flows through the n⁻-type epitaxial layer 2 in the vertical direction from the bottom of the n⁺-type contact layer 4 to the p-type semiconductor substrate 1. The n⁺-type contact layer 4 has a bottom area larger than a sidewall area to thereby cause breakdown current density to be low. This enables the semiconductor device of the embodiment to enhance ESD tolerance of the ESD protection diode while maintaining the area that the ESD protection diode occupies in a chip.

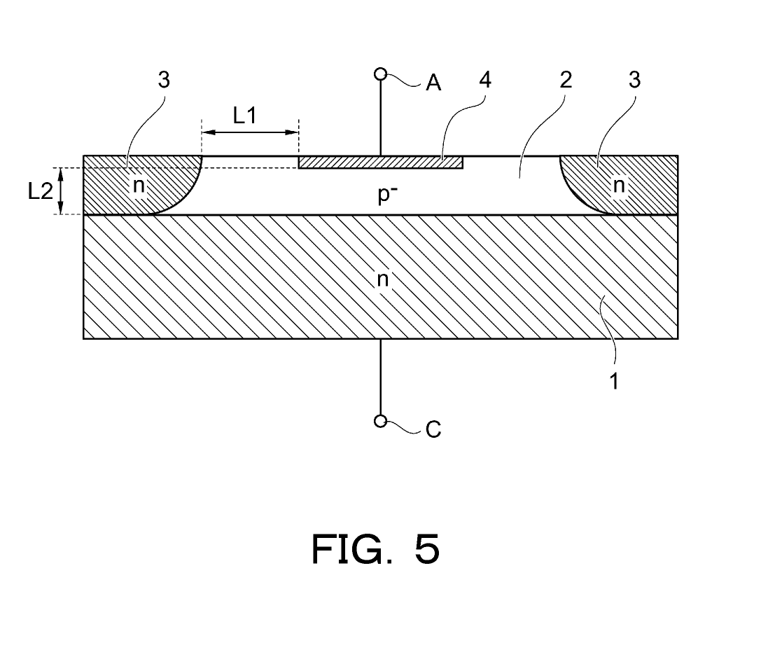

FIG. 5 is a sectional view showing a second modification of the first embodiment. As shown in FIG. 5, the semiconductor device in accordance with the second modification has semiconductor layers each having a conductivity type opposite to the conductivity type of the corresponding semiconductor layer in the semiconductor device of the first embodiment. In the semiconductor device of the second modification, the first conductivity type is an n-type, and the second conductivity type is a p-type. A first electrode is a cathode electrode C, and the second electrode is an anode electrode A.

In the semiconductor device of the second modification, current flows in a direction opposite to the current flowing in the semiconductor device of the first embodiment. The semiconductor device of the second modification differs from the semiconductor device of the first embodiment only in a current-flow direction. The semiconductor device of the second modification has the same operations and effects as the semiconductor device of the first embodiment.

### Second Embodiment

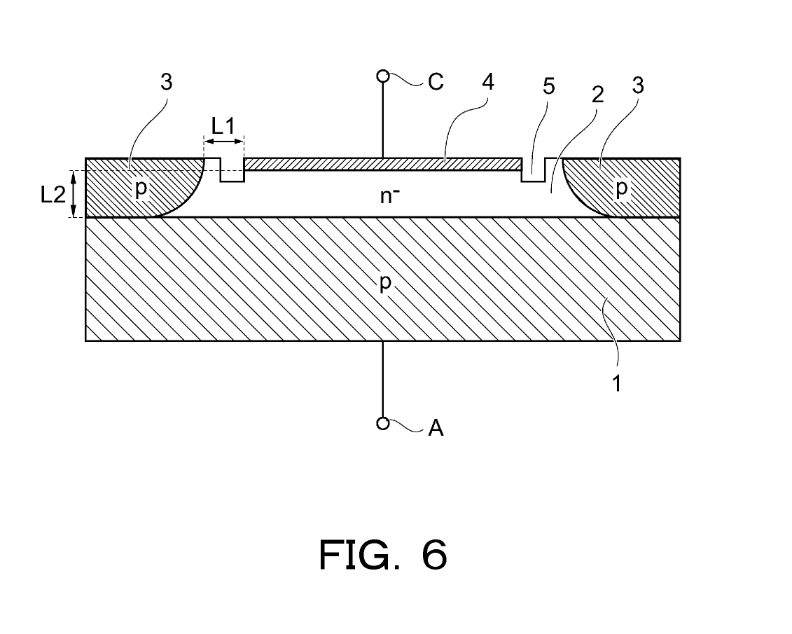

A semiconductor device in accordance with a second embodiment will be described with reference to FIG. 6. FIG. 6 is a sectional view showing the semiconductor device in accordance with the second embodiment. The same portions or the like will be denoted by the same reference numerals as in the first embodiment. The same description will not be repeated, and different points will be described.

As shown in FIG. 6, a trench 5 is provided around the n⁺-type contact layer 4 and in the n⁻-type epitaxial layer 2 in the semiconductor device of the second embodiment. The trench 5 extends more deeply than the bottom of the n⁺-type contact layer 4. In the semiconductor device of this embodiment, L2 denotes a separation distance between the n⁺-type contact layer 4 and the p-type semiconductor substrate 1 in the vertical direction, and L1 denotes a shortest distance between the n⁺-type contact layer 4 and the p-type semiconductor layer 3 in the horizontal direction. L1 and L2 are not mutually limited. The semiconductor device of the second embodiment differs from the semiconductor device of the first embodiment in the several points mentioned just above.

The semiconductor device of this embodiment has the trench 5 on the surface of the n⁻-type epitaxial layer 2 between the n⁺-type contact layer 4 and the p-type semiconductor layer 3. This trench serves as a capacitor with small capacitance. A reverse bias applied between the anode electrode A and the cathode electrode C is almost the same as the voltage between the n⁺-type contact layer 4 and the p-type semiconductor layer 3. Most of the reverse bias is applied across the trench 5.

As a result, few breakdowns occur at a p-n junction made up by the n⁻-type epitaxial layer 2 and the p-type semiconductor layer 3 in the horizontal direction. For this reason, in the semiconductor device of this embodiment without a relation of L2<L1, a breakdown occurs between the n⁺-type contact layer 4 and the p-type semiconductor substrate 1 in the vertical direction. As a result, a breakdown current flows from the bottom of the n⁺-type contact layer 4 through the n⁻-type epitaxial layer 2 to the p-type semiconductor substrate 1. The semiconductor device of the second embodiment enhances ESD tolerance of the ESD protection diode while maintaining the area that the ESD diode occupies in a chip as well as the semiconductor device of the first embodiment.

Without a limitation of L2<L1, the semiconductor device of the second embodiment causes a breakdown between the n⁺-type contact layer 4 and the p-type semiconductor substrate 1 in the vertical direction. The semiconductor device of the second embodiment enables the area of the n⁺-type contact layer 4 to be larger than the semiconductor device of the first embodiment. As a result, the semiconductor device of the second embodiment enables it to enhance the ESD tolerance of the ESD protection diode.

Unfortunately, an extremely short L1 causes a pathway from the bottom of the n⁺-type contact layer 4 to the p-type semiconductor layer 3 to be shorter than the distance L2. In this case, a breakdown will occur in the pathway. As L1 becomes shorter, the deeper trench 5 needs to be dug more deeply so that the pathway is longer than L2, thereby preventing the breakdown from occurring in the pathway. Alternatively, the trench 5 may be formed such that the trench 5 reaches the p-type semiconductor substrate 1 in order to cause a breakdown in the pathway from the bottom of the n⁺-type contact layer 4 to the p-type semiconductor substrate 1.

### Third Embodiment

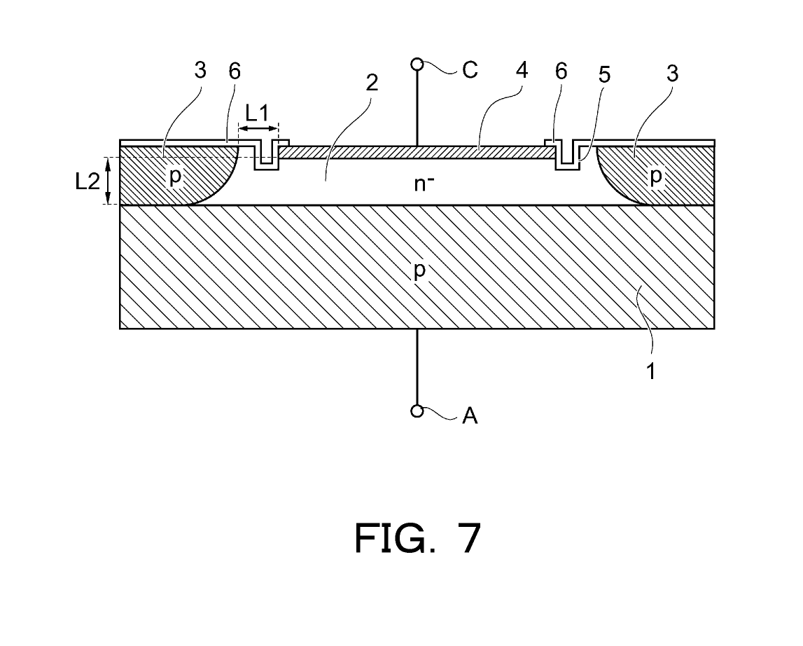

A semiconductor device in accordance with a third embodiment will be described with reference to FIG. 7. FIG. 7 is a sectional view showing the semiconductor device in accordance with the third embodiment. The same portions or the like will be denoted by the same reference numerals as in the second embodiment. The same description will not be repeated, and different points will be described.

As shown in FIG. 7, the semiconductor device of the third embodiment further includes an insulating film 6 that covers the sidewall and bottom of the trench 5 whereas the semiconductor device of the second embodiment has no insulating film. Materials of the insulating film 6 include silicon oxide, silicon nitride, and silicon oxynitride. Alternatively, the insulating film 6 may be provided onto the surfaces of the n−-type epitaxial layer 2 and the p-type semiconductor layer 3 in addition to the inside of the trench 5. The third embodiment differs from the second embodiment in the insulating film 6.

The insulating film 6 allows it to prevent the semiconductor device of the third embodiment from short-circuiting inside the trench 5 by invasion of foreign substances. The semiconductor device of the third embodiment brings the same effects as well as the semiconductor device of the second embodiment in addition to the prevention of the short-circuiting.

### Fourth Embodiment

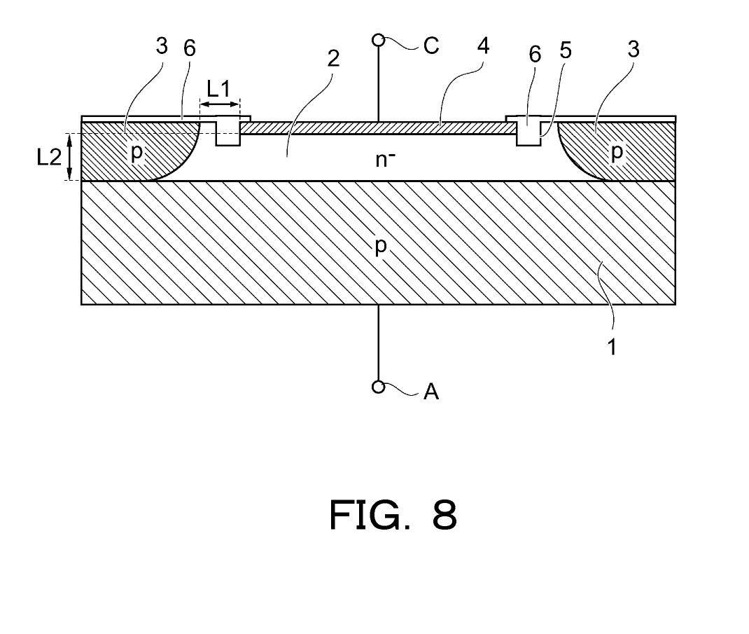

A semiconductor device in accordance with a fourth embodiment will be described with reference to FIG. 8. FIG. 8 is a sectional view showing the semiconductor device in accordance with the fourth embodiment. The same portions or the like will be denoted by the same reference numerals as in the third embodiment. The same description will not be repeated, and different points will be described.

The semiconductor device of the fourth embodiment includes an insulating film 6 that fills the trench 5. The fourth embodiment differs from the third embodiment in this point. The trench 5 filled with the insulating film 6 serves as a capacitor with large capacitance. The semiconductor device of the fourth embodiment brings the same effects as well as the semiconductor device of the third embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimd is:

1. A semiconductor device, comprising:
a semiconductor substrate of a first conductivity type;
a first semiconductor layer of a second conductivity type, the first semiconductor layer provided on the semiconductor substrate;
a second semiconductor layer of a first conductivity type, the second semiconductor layer reaching the semiconductor substrate from a surface of the first semiconductor layer and surrounding the first semiconductor layer;
a third semiconductor layer of a second conductivity type, the third semiconductor layer separated from the second semiconductor layer, surrounded by the second semiconductor layer, and having a higher concentration of second-conductivity-type impurities than the first semiconductor layer;
a first electrode connected to the semiconductor substrate; and
a second electrode connected to the second semiconductor layer, wherein
a withstand voltage between the semiconductor substrate and the third semiconductor layer is lower than a withstand voltage between the second semiconductor layer and the third semiconductor layer.

2. The semiconductor device according to claim 1, wherein
a shortest separation distance between the second semiconductor layer and the third semiconductor layer in a direction parallel to the first semiconductor layer is larger than a separation distance between a bottom of the third semiconductor layer and an upper surface of the semiconductor substrate in a direction vertical to the first semiconductor layer.

3. The semiconductor device according to claim 1, wherein
a trench is provided to the first semiconductor layer along an outer circumference of the third semiconductor layer, extending more deeply than a bottom of the third semiconductor layer.

4. The semiconductor device according to claim 3, further comprising an insulating film to cover a sidewall and a bottom of the trench.

5. The semiconductor device according to claim 4, further comprising an insulating film to fill the trench.

6. The semiconductor device according to claim 3, wherein
a shortest first separation distance between the second semiconductor layer and the third semiconductor layer in a direction parallel to the first semiconductor layer is shorter than a second separation distance between the bottom of the third semiconductor layer and an upper surface of the semiconductor substrate in a direction vertical to the first semiconductor layer.

7. The semiconductor device according to claim 6, wherein
a pathway from the exposed bottom edge of the third semiconductor layer to the second semiconductor layer is longer than the second separation distance.

8. The semiconductor device according to claim 7, wherein
the trench reaches the semiconductor substrate.

9. The semiconductor device according to claim 1, wherein
an impurity concentration in the third semiconductor layer decreases from a surface of the third semiconductor layer toward a bottom of the third semiconductor layer, and is the same as the impurity concentration of the first semiconductor layer at the bottom of the third semiconductor layer.

10. The semiconductor device according to claim 1, wherein
the first conductivity type is a p-type, and the second conductivity type is an n-type.

11. The semiconductor device according to claim 1, wherein
the first conductivity type is an n-type, and the second conductivity type is a p-type.

12. A semiconductor device, comprising:
a semiconductor substrate of a first conductivity type;
a first semiconductor layer of a second conductivity type, the first semiconductor layer provided on the semiconductor substrate and having a trench;
a second semiconductor layer of a first conductivity type, the second semiconductor layer reaching the semiconductor substrate from a surface of the first semiconductor layer and surrounding the first semiconductor layer;
a third semiconductor layer of a second conductivity type, the third semiconductor layer separated from the second semiconductor layer, surrounded by the second semiconductor layer, and having a higher concentration of second-conductivity-type impurities than the first semiconductor layer;
a first electrode connected to the semiconductor substrate; and
a second electrode connected to the second semiconductor layer,
the trench provided along an outer circumference of the third semiconductor layer, extending from the surface toward the substrate, and more deeply than a bottom of the third semiconductor layer, wherein
a withstand voltage between the substrate and the third semiconductor layer is lower than a withstand voltage between the second semiconductor layer and the third semiconductor layer.

13. The semiconductor device according to claim 12, further comprising an insulating film to cover a sidewall and a bottom of the trench.

14. The semiconductor device according to claim 12, further comprising an insulating film to fill the trench.

15. The semiconductor device according to claim 12, wherein
a shortest first separation distance between the second semiconductor layer and the third semiconductor layer in a direction parallel to the first semiconductor layer is shorter than a second separation distance between a bottom of the third semiconductor layer and an upper surface of the semiconductor substrate in a direction vertical to the first semiconductor layer.

16. The semiconductor device according to claim 15, wherein
a pathway from the exposed bottom edge of the third semiconductor layer to the second semiconductor layer is longer than the second separation distance.

17. The semiconductor device according to claim 16, wherein
the trench reaches the substrate.

18. The semiconductor device according to claim 12, wherein
an impurity concentration in the third semiconductor layer decreases from a surface of the third semiconductor layer toward the bottom of the third semiconductor layer, and is the same as the impurity concentration of the first semiconductor layer at the bottom of the third semiconductor layer.

19. The semiconductor device according to claim 12, wherein
the first conductivity type is a p-type, and the second conductivity type is an n-type.

20. The semiconductor device according to claim 12 wherein
the first conductivity type is an n-type, and the second conductivity type is a p-type.
